(19) United States
(12) Patent Application Publication
(10) Pub. No.: US 2017/0203380 A1
(43) Pub. Date: Jul. 20, 2017

(54) CAPILLARY BLOCK

(71) Applicant: Indium Corporation, Clinton, NY (US)

(72) Inventors: Jordan Peter Ross, Whitesboro, NY (US); Bernard Allen Leavitt, JR., Dolgeville, NY (US)

(73) Assignee: Indium Corporation, Clinton, NY (US)

(21) Appl. No.: 15/001,480

(22) Filed: Jan. 20, 2016

(51) Int. Cl. B23K 3/06; H01L 23/04; B23K 35/36; H01L 21/48; B23K 1/00; B23K 35/02

(52) U.S. Cl. CPC B23K 3/0623; B23K 1/0016; B23K 35/0222; B23K 35/36; H01L 21/4817; H01L 23/04

(57) ABSTRACT

A capillary block can be provided in any of a number of different geometries for soldering and brazing. The capillary block can be configured to be positioned adjacent a joint to be formed prior to heating. Heat can then be applied to melt the capillary block and cause it to wick into the interface between the members being joined. The capillary block can be used in place of or in addition to a frame preform to create a joint such as a wall-to-floor joint of an assembly.

### TECHNICAL FIELD

The disclosed technology relates generally to solder or braze materials, and more particularly, some embodiments relate to a capillary block for solder or braze applications.

### DESCRIPTION OF THE RELATED ART

Solder and braze are used to make electrical, mechanical, and thermal connections in a wide variety of applications. The soldering and brazing processes are used to join metal items together by melting and flowing the solder or braze material into the joint between the items and then allowing it to cool and harden. The solder and braze materials are generally metals or alloys, and typically have a lower melting temperature than that of the metals being joined. For example, metals such as silver, gold, bismuth in elemental, alloyed, or chemical compound forms can be used. In many cases, alloys are chosen of specific compositions to achieve desired properties or results, depending on the application. These can include, for example, flow or reflow properties of the material; thermal and electrical properties of the joint; and joint property such as strength, drop-test performance, reliability and so on.

When soldering or brazing it is common to place a solder or braze preform under a wall in order to create a joint. A solder preform, such as a frame preform, is a defined shape and size of a solder alloy. It can be used in place or in conjunction with a solder paste to join two items together. For example, in the case of a microelectronic package, can be used to attach the package cover and the sidewalls to the microelectronic package. An example of this is shown in FIG. 1, which provides a cross-sectional view of a microelectronic package. This example includes sidewalls 104 and a package cover 106 assembled to enclose a semiconductor chip 108. Sidewalls 104 are attached to the package base 110 using a solder or braze frame preform 112. Similarly, package cover 106 is attached to the sidewalls using frame preform 114. When heat is applied frame preforms 112, 114 melt and subsequently harden after the heat is removed to form the desired joint. In the case of sidewalls 104 and base 110 a joint sometimes referred to as a wall-to-floor joint is formed.

In cases where frame preforms are used to join components such as these, the prefabricated piece of solder or braze must be geometrically specific to the package and can only be used for that geometry. Also, the preform must be included during package assembly and therefore dictates part of the assembly sequence.

### BRIEF SUMMARY OF EMBODIMENTS

According to various embodiments, a capillary block can be provided in any of a number of different geometries for soldering and brazing. The capillary block can be configured to be positioned adjacent the joint to be formed prior to heating. Heat can then be applied to melt the capillary block and cause it to wick into the joint. In various embodiments, the capillary block can be used in place of or in addition to a frame preform to create a joint such as for example a wall-to-floor joint in the assembly.

A method for reflow soldering or brazing first and second members of a package using a braze or solder preform can include in various embodiments assembling the package by joining the first and second members prior to adding the braze or solder preform; adding the braze or solder preform to the assembled package adjacent an interface formed between the first and second members; and heating the assembly to above a melting point of the braze or solder preform, causing melted material of the braze or solder preform to wick into the interface between the first and second members.

The process can include inspecting the assembled package after assembly and prior to heating to determine a gap volume of the interface between the first and second members, and selecting a geometry of the braze or solder preform based on the determined gap volume. The process can further include inspecting the assembled package after the heating operation to determine whether an additional volume of solder or braze is needed.

The process in some embodiments includes positioning a second braze or solder preform adjacent the interface and reheating the assembly to above a melting point of the second braze or solder preform causing material of the braze or solder preform to melt and wick into the joint, thereby adding additional solder material to the joint.

The braze or solder preform can be configured to be trimmed prior to heating to adjust the volume and reduce braze blush. The braze or solder preform can be configured to include at least one flat side such that the preform can be positioned adjacent the interface. It may also be configure to include at least one flat surface to keep the block from rolling in the assembly prior to heating.

In some embodiments, the braze or solder preform has a geometry configured to be placed adjacent and in touching relationship with at least one of the first and second members. The braze or solder preform further comprises a volume of solder or braze material having a geometry that is complementary to the first and second members after assembly.

In another embodiment, a capillary preform, having a volume of solder or braze material defining a length, width, and height, includes at least one flat surface such that the capillary preform can be positioned adjacent an interface, wherein, the capillary preform is configured to be positioned for reflow after package assembly. The flat surface may be configured to keep the block from rolling in the assembly prior to heating.

Other features and aspects of the disclosed technology will become apparent from the following detailed description, taken in conjunction with the accompanying drawings, which illustrate, by way of example, the features in accordance with embodiments of the disclosed technology. The summary is not intended to limit the scope of any inventions described herein, which are defined solely by the claims attached hereto.

### BRIEF DESCRIPTION OF THE DRAWINGS

The technology disclosed herein, in accordance with one or more various embodiments, is described in detail with reference to the following figures. The drawings are provided for purposes of illustration only and merely depict typical or example embodiments of the disclosed technology. These drawings are provided to facilitate the reader's understanding of the disclosed technology and shall not be considered limiting of the breadth, scope, or applicability thereof. It should be noted that for clarity and ease of illustration these drawings are not necessarily made to scale.

FIG. 1 is a diagram illustrating an example of an assembled package.

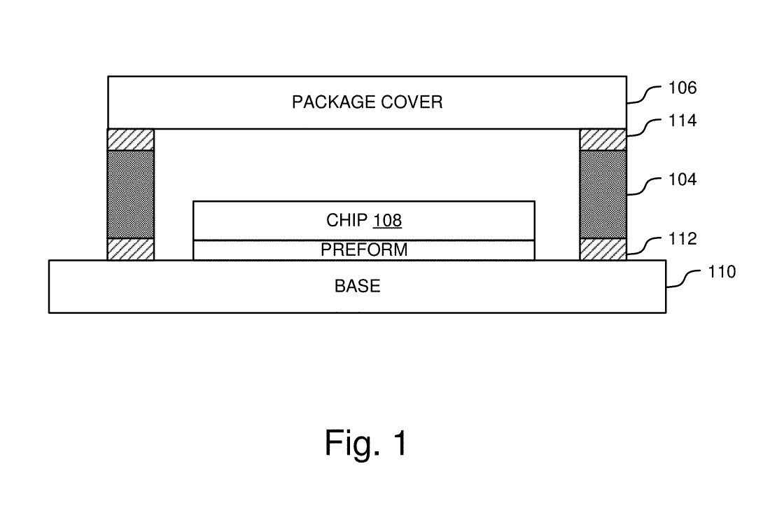

FIG. 2 is a diagram illustrating an example of an assembly including two members and a capillary block as a solder preform in accordance with one embodiment of the systems and methods described herein.

FIG. 3 is a diagram illustrating a cross-sectional view of a capillary block adjacent an interface between first and second members being joined in accordance with one embodiment of the systems and methods described herein.

FIG. 4 is a diagram illustrating example geometries for a capillary block in accordance with various embodiments.

The figures are not intended to be exhaustive or to limit the invention to the precise form disclosed. It should be understood that the invention can be practiced with modification and alteration, and that the disclosed technology be limited only by the claims and the equivalents thereof.

### DETAILED DESCRIPTION OF THE EMBODIMENTS

Embodiments of the technology disclosed herein are directed toward capillary block elements for soldering and brazing. According to various embodiments, a capillary block can be provided in any of a number of different geometries for soldering and brazing. The capillary block can be configured to be positioned adjacent the joint to be formed prior to heating. Heat can then be applied to melt the capillary block and cause it to wick into the joint. In various embodiments, the capillary block can be used in place of or in addition to a frame preform to create a joint such as for example a wall-to-floor joint in the assembly.

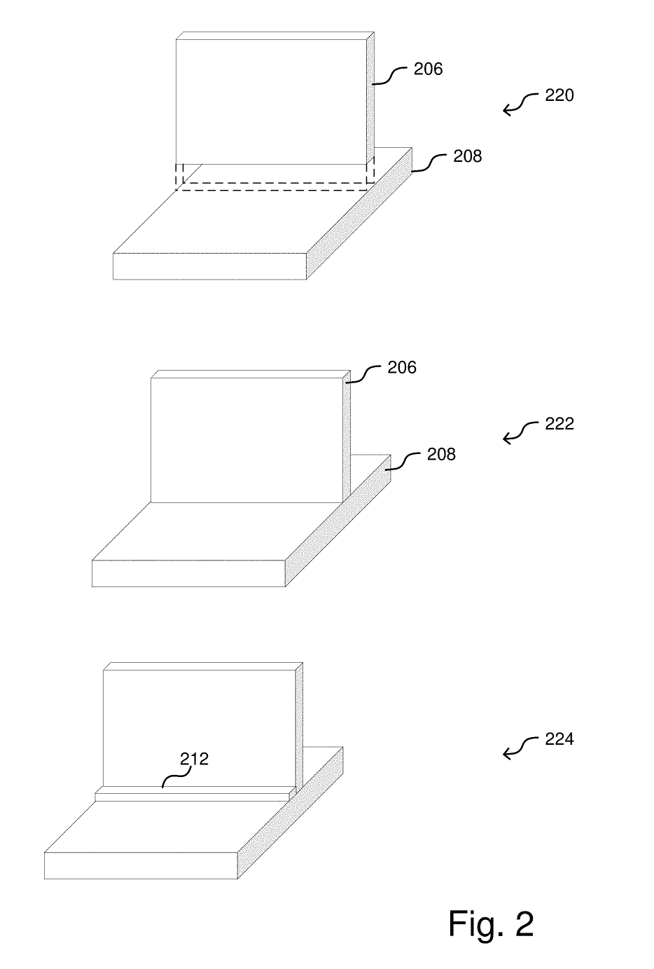

FIG. 2 is a diagram illustrating an example use of the capillary block in accordance with one embodiment of the systems and methods described herein. FIG. 2 illustrates a first member 206 being joined to a second member 208 using an example capillary block 212. Although first and second members 206, 208 can be any of a number of different components capable of being joined by a solder or brazing material, consider an example in which first member 206 is a side wall of electronic component or housing and second member 208 is a base on which the sidewall is being mounted. In the top rendering 220 of FIG. 2, first member 206 is spaced apart from second member 208 and ready for assembly. The dashed lines indicate the direction of movement of first member 206 for the assembly process. In the center rendering 222 of FIG. 2, first member 206 is placed adjacent second member 208. It is noted that in this example no preform (e.g. no frame preform or other solder preform) is positioned between first member 206 and a second member 208. Accordingly, these components can be assembled prior to the addition of a solder element or preform.

In the bottom rendering 224 of FIG. 2, first member 206 and second member 208 are abutted against one another and capillary block 212 is positioned adjacent the interface between first and second members 206, 208. Capillary block 212 can be made of a particular metal or alloy depending on the members being joined and the desired characteristics of the joint.

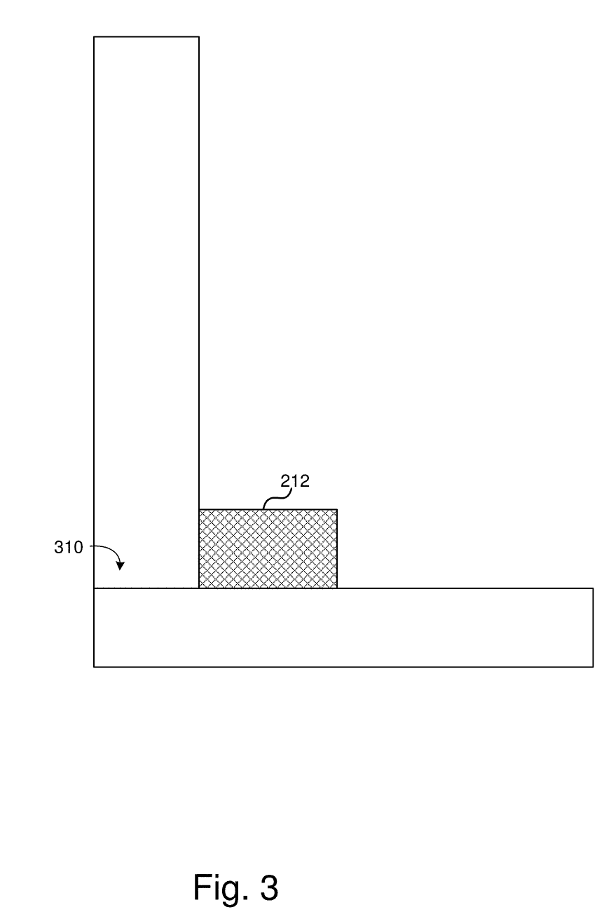

FIG. 3 is a diagram illustrating a cross-sectional view of a capillary block positioned adjacent a joint to be formed 310. In this example, capillary block 212 is rectangular in shape with relatively smooth, flat edges, so that it can be placed against the members to be joined. Providing at least one relatively flat surface one the capillary block allows the capillary block to be positioned in place adjacent the joint without requiring a mechanism to hold it. This can keep the block from rolling out of position prior to heating. As this illustrates, the capillary block in this example has two flat surfaces, each surface configured to be in touching relation to the surface of its corresponding assembly member. Accordingly, the capillary block has a geometry that is complementary to the assembly members after they have been assembled and before heat is applied to melt the block. This can be useful, for example, to have the preform fit closely adjacent and in touching relation to surfaces of each member of the assembly where they meet.

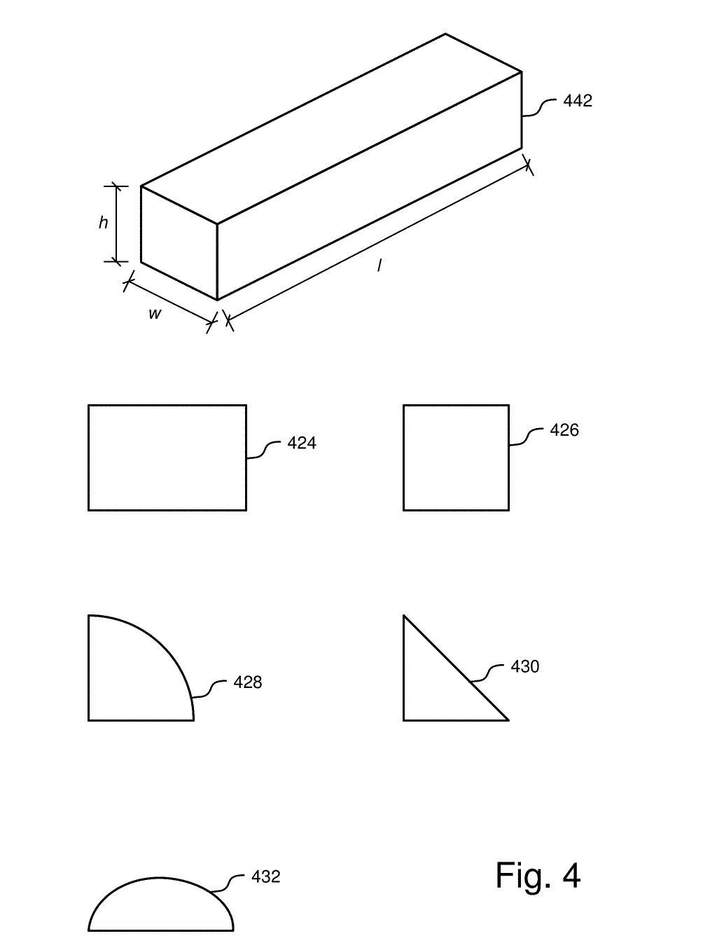

Although illustrated as having a rectangular cross-section, in other embodiments the capillary block can have a square cross-section, while in still further embodiments, the capillary block can have other cross-sectional geometries as shown in FIG. 4 (described below). With reference now to FIG. 4, illustrated now are an exemplary capillary block (whose dimensions are not necessarily shown in proportion) having a rectangular cross-section and having a length greater than either its width or its height. In this example, its length, I, is also greater than its width, w, and height, h, combined. Cross-section 424 provides an example of a rectangular cross-section for a capillary block. Cross-section 426 provides an example of a square cross-section for a capillary block. As further examples, the capillary block can include rounded edges such as the examples illustrated at 428 (two flat edges edges) and 432 (one flat edge). Also, a triangular cross-section can be provided as illustrated by the example at 430. As these examples serve to illustrate, any of a number of different geometries can be used for the capillary block depending on the application and the amount of material needed to form a proper joint.

The dimensions of the capillary block (length, width, and height) can be selected based on the size of the joint and the volume to be filled between the members being connected. In other words, sufficient bulk can be provided to ensure that sufficient solder or braze material is available to form a joint of the desired characteristics (e.g., strength, thermal or electrical conductivity, etc.). In one embodiment, for example, the capillary block can have a square cross-section of anywhere between 0.020″ and 0.100″ across, although dimensions outside this range can be used. For example, a capillary block with a square cross-section may have dimensions of 0.020″×0.020″, 0.030″×0.030″, 0.040″×0.040″, 0.050″×0.050″ and so on. A capillary block with a rectangular cross-section may be configured with a length and width within this range, or be on this range, as well.

The length of the capillary block can be selected based on the length of the joint (e.g. wall length) being formed. In some embodiments, the capillary block is selected to be the same length as the joint length such as a sufficient amount of material can be wicked into the joint. In other embodiments, the length of the capillary block can be slightly less than the length of the joint as the material will not only wick into the joint adjacent the block, but will also wick lengthwise beyond the length of the block along the joint.

In further embodiments, the length of the capillary block can be sufficiently short such that multiple blocks are used to extend the length of the joint. Accordingly, in various configurations multiple blocks can be used in order to increase or decrease the volume, and the geometry of the block is not specific to the package, therefore it can be used in multiple applications. Capillary blocks can be fabricated in standard geometries and dimensions for general applications. In other embodiments, the capillary blocks can be fabricated to specification for unique or custom applications.

As the examples in FIG. 4 serve to illustrate, it is preferred that the geometry of capillary block in the form of a block or other shape with at least one flat edge, rather having than a round or circular cross-section. Having one, and preferably two, flat edges allows the capillary block to be butted up against either or both members being joined (e.g. the and the wall of the package) so that when it melts a can wick under the interface between the two members through capillary action. Because melted solder and braze materials will tend to wick or “wet out” only so far, providing a geometry that allows close placement to the joint can be desired. For example, where the two members being joined are placed at right angles to one another, a square or rectangular shape capillary block with a squared, 90°, corner allows the capillary block material to be butted as close to the interface as practical.

Braze blush is a common side effect from using too much braze or having a non-optimized reflow profile. In various embodiments, the capillary block can be configured such that one can easily add or reduce the amount of braze being used in the assembly by trimming a block to reduce volume or adding more blocks to increase volume. Thus, the capillary block can effectively be “resized” to provide the desired amount of material to form a joint. This can be an advantage over a solder or braze frame, which cannot be adjust in mid assembly.

In various embodiments, flux can be included with the capillary block to increase performance of the solder or braze. For example, in one embodiment the capillary block can be coated with a flux coating to remove oxide during reflow. In another embodiment, the capillary block can have one or more flux cores internal to the capillary block. In yet a further embodiment, a combination of an external coating and one or more internal cores of flux can be provided. In other embodiments, flux, such as a liquid flux, can be applied directly to the workpiece before the capillary block is positioned in place.

Because the capillary block does not have to be interposed between components as does a solder or braze frame, the package can be assembled prior to adding the braze or solder capillary block. Also, because the capillary block can be configured to butt up against the package wall (or other member being used in the assembly) the assembler can pre-assemble the package and look for gaps or adjust alignment. Then, after this preassembly inspection is performed, the user can add the needed amount of braze or solder material (e.g. add the appropriate geometry capillary block or blocks) based on the amount of gap. For example, gap volume calculations can be performed after the package is preassembled to determine the amount of solder or braze that will be required to adequately fill the gap. In some embodiments, electronic inspection tools can be used to determine the edges of the members being joined and calculate the gap volumes there between.

Additionally, capillary blocks can be used in reworked processes to provide additional solder or braze two joints that have already been formed (whether using capillary blocks, solder or braze frames, or other materials in the original joint formation). For example, a completed joint can be inspected to determine whether sufficient solder or braze is present to meet the desired joint characteristics. For example, the joint can be inspected to determine whether hermetic seal has been formed, sufficient material is present for a proper bond, the proper thermal or electrical conductivity characteristics will be met, and so on. Where it is determined that additional solder or braze material needs to be applied, and additional block can be added to the assembly (e.g., positioned adjacent the unsatisfactory joint) and the assembly sent through the reflow profile again.

Also, because the capillary block is not necessarily specific to the geometry of the package as is the case with a frame of preformed, special tooling is not always necessary if the members being joined are not to spec or otherwise of other geometry or configuration than expected. The user can an appropriate geometry, and even adjust geometry such as by trimming or shaving off of the length, width, or height of the block, to provide a desired geometry for the application.

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that can be included in the disclosed technology. The disclosed technology is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the technology disclosed herein. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the disclosed technology is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A method for reflow soldering or brazing first and second members of a package using a braze or solder preform, comprising:
assembling the package by joining the first and second members prior to adding the braze or solder preform;
adding the braze or solder preform to the assembled package adjacent an interface formed between the first and second members; and
heating the assembly to above a melting point of the braze or solder preform, causing melted material of the braze or solder preform to wick into the interface between the first and second members.

2. The method of claim 1, further comprising inspecting the assembled package after assembly and prior to heating to determine a gap volume of the interface between the first and second members, and selecting a geometry of the braze or solder preform based on the determined gap volume.

3. The method of claim 1, further comprising inspecting the assembled package after the heating operation to determine whether an additional volume of solder or braze is needed.

4. The method of claim 3, further comprising positioning a second braze or solder preform adjacent the interface and reheating the assembly to above a melting point of the second braze or solder preform causing material of the braze or solder preform to melt and wick into the joint.

5. The method of claim 1, further comprising trimming the braze or solder preform prior to heating to adjust the volume and reduce braze blush.

6. The method of claim 1, wherein the braze or solder preform further comprises a flux coating disposed on an exterior surface of the preform.

7. The method of claim 1, wherein the braze or solder preform further comprises a flux core disposed within the preform.

8. The method of claim 1, wherein the braze or solder preform further comprises at least one flat side such that the preform can be positioned adjacent the interface.

9. The method of claim 1, wherein the braze or solder preform further comprises at least one flat surface to keep the block from rolling in the assembly prior to heating.

10. The method of claim 1, wherein the braze or solder preform further comprises a volume of solder or braze material having a geometry configured to be placed adjacent and in touching relationship with at least one of the first and second members.

11. The method of claim 1, wherein the braze or solder preform further comprises a volume of solder or braze material having a geometry that is complementary to the first and second members after assembly.

12. The method of claim 1, wherein the braze or solder preform is of a length chosen to match a length of the interface between the first and second members.

13. A capillary preform, comprising a volume of solder or braze material defining a length, width, and height, and comprising at least one flat surface such that the capillary preform can be positioned adjacent an interface, wherein, the capillary preform is configured to be positioned for reflow after package assembly.

14. The capillary preform of claim 13, further comprising a flux coating disposed on an exterior surface of the capillary preform.

15. The capillary preform of claim 13, further comprising a flux core disposed within the volume of the capillary preform.

16. The capillary preform of claim 13, wherein the flat surface is further configured to keep the block from rolling in the assembly prior to heating.
